(19) United States
(12) Patent Application Publication
(10) Pub. No.: US 2008/0026231 A1
(43) Pub. Date: Jan. 31, 2008

(54) Method for Metallizing the Pre-Passivated Surface of a Semiconductor Material Obtained by Said Method

(75) Inventors: Claudio Radtke, Porto Alegre (BR); Mathieu Silly, Saint Victor De Buthon (FR); Patrick Soukiassian, St Remy Les Cheureuse (FR); Hanna Enriquez, Paris (FR)

Correspondence Address: THELEN REID BROWN RAYSMAN & STEINER LLP, P. O. BOX 640640, SAN JOSE, CA, 95164-0640, US

(73) Assignees: COMMISSARIAT A L'ENERGIE ATOMIQUE, Paris (FR); UNIVERSITE PARIS SUD XI, ORSAY (FR)

(21) Appl. No.: 11/630,452

(22) PCT Filed: Jun. 20, 2005
(86) PCT No.: PCT/FR05/50469

§ 371 Date: Dec. 20, 2006

(30) Foreign Application Priority Data
Jun. 21, 2004 (FR) 04 06751

(51) Int. Cl. B32B 15/04; H01L 21/44

(52) U.S. Cl. 428/457; 438/602; 257/E21.476

(57) ABSTRACT

Method for metallizing the pre-passivated surface of a semiconductor material and material obtained by said method.

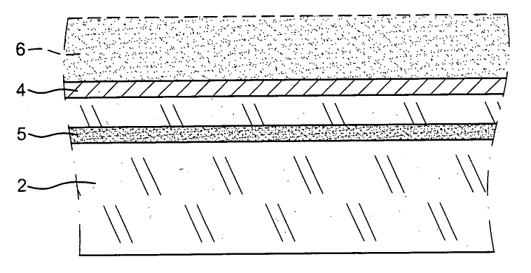

According to the invention, which is applied in particular in microelectronics, the material surface (2) is prepared so that it has bonds capable of adsorbing atoms of hydrogen or of a metal element, one ore several layers are passivated, preferably immediately underneath the surface, by exposing it to a passivation compound, and the surface (4) is metallized by exposure to atoms of hydrogen or of the metal element.

### TECHNICAL FIELD

This invention relates to a method for metallizing the surface of a semiconductor material, in particular using hydrogen, as well as the material with a metallized surface that is obtained by said method.

As will be seen below, the invention has numerous applications, in particular in microelectronics.

### PRIOR ART

To produce devices, in particular bipolar transistors, diodes and unipolar transistors such as MOS, MOSFET and MESFET transistors, which are based on semiconductors, it is necessary to form metal “contacts”. This is commonly done by deposition of layers of a metal that can be selected in particular from Au, Al, Cu and transition metals such as Ti, W and Ni.

The tendency toward miniaturization leads to the use of increasingly thin layers and to the search for increasingly abrupt metal/semiconductor interfaces.

However, a problem is posed: most metals, in any case those that are most advantageous, form alloys with the substrates on which they are deposited. This results in little abrupt interfaces, which have lower performances.

Therefore, to form, for example, a MOS transistor, it is necessary to deposit a metal layer on an oxide, itself deposited on a semiconductor.

### DISCLOSURE OF THE INVENTION

This invention is intended to overcome the aforementioned disadvantages.

The method of the invention makes it possible not only to use very thin metal layers, but also to obtain abrupt interfaces.

This method of the invention makes it possible to work with precision at the atomic scale and therefore at the level of the atomic layer. It thus makes it possible to obtain an abrupt interface between two layers with distinct electric properties. For example, it makes it possible to obtain an abrupt interface between a metal layer and a semiconductor layer.

Admittedly, a method for treating the surface of a semiconductor material is already known from the following document to which reference will be made: (1) International application PCT/FR02/01323, filed on 17 Apr. 2002, invention of V. Derycke and P. Soukiassian, international publication number WO 02/086202A.

In this document (1), it was shown that atomic hydrogen could metallize the surface of silicon carbide by the creation of specific defects, contrary to its well-known role as an agent for passivation of the surfaces of semiconductor materials.

However, in this case, only an abrupt interface is possible between a metal layer, which is due to the hydrogen, and a semiconductor layer (SiC layer).

Specifically, this invention relates to a method for treating a semiconductor material, so as to put the surface of said material in an electrically conductive state, which method is characterised in that it includes the following steps:
a preparation step in which said surface is prepared so that it has bonds capable of adsorbing hydrogen atoms or atoms of at least one metal element,
a passivation step in which one or more layers are passivated, preferably immediately underneath said surface, by exposing said surface to a passivation compound, and
a metallization step in which the surface is metallized by exposure to hydrogen atoms or to atoms of the metal element,

wherein the preparation and the combination of the surface with hydrogen or with the metal element cooperate to obtain the electrically conductive state of the surface,

the method possibly also including a step of partial depassivation of the passivated layer(s), which follows the passivation step.

The steps can be carried out in any order: in this method, it is possible, for example, to use the following order for these steps:
preparation, then passivation, then possibly depassivation, then metallization, or
passivation, then possibly depassivation, then preparation, then metallization.

Thus, according to a specific embodiment of the invention, the depassivation step follows the passivation step and is itself followed by the preparation step, then by the metallization step.

The semiconductor material is preferably monocrystalline.

According to a first specific embodiment of the invention, the passivation of the layer(s) is performed by oxidation of this or these layer(s), by exposing the surface to an oxidizing compound.

According to a second specific embodiment, the passivation of the layer(s) is performed by oxynitriding of said layer(s), by exposing the surface to an oxynitriding compound.

According to a third specific embodiment, the passivation of the layer(s) is performed by nitriding said layer(s), by exposing the surface to a nitriding compound.

The bonds capable of absorbing hydrogen atoms or atoms of the metal element are preferably dangling bonds.

According to a preferred embodiment, of the invention, the semiconductor material is silicon carbide.

Preferably, the surface of the silicon carbide is prepared so as to have, at the atomic scale, a symmetric 3×2 controlled organisation.

In this invention, the layers that are passivated can be layers immediately underneath the surface.

According to a preferred embodiment of this invention, the metallized surface is exposed to oxygen so as to reinforce the metallization of said surface.

This invention also relates to a semiconductor material, preferably monocrystalline, of which the surface is metallized by the treatment method of the invention.

This invention also relates to a solid composite material including a semiconductor substrate of which the surface is metallized, said material being characterised in that said surface covers one or several atomic layers of the substrate, which are passivated and are preferably immediately underneath said surface, and in that the interface between the passivated atomic layer(s) and the substrate as well as the interface between the passivated atomic layer(s) and the metallized surface are abrupt.

In this invention, the term “abrupt interface” refers to an interface in which a sudden change in composition and/or structure occurs between the two materials on each side of the interface.

Typically, this abrupt change occurs in a space consisting of two to three monoatomic layers.

Typically, the metallized layer has a thickness of 1 to 3 monoatomic layers.

The surface preferably has dangling bonds, said surface being metallized, i.e. made electrically conductive, by the adsorption of hydrogen atoms or atoms of a metal element.

The material is preferably silicon carbide with a cubic structure, of which the surface has, at the atomic scale, a symmetric 3×2 controlled organisation.

This invention also relates to a method for producing an electrical contact at the surface of a semiconductor material, in which said contact is produced by metallizing the surface of the material by the treatment method of the invention.

This invention also relates to a method for producing an interface between a semiconductor material and a biological material, in which said interface is produced by metallizing the surface of the material by the treatment method of the invention.

This invention also relates to a method for reducing the friction coefficient of a surface of a semiconductor material, in which said surface is metallized by the treatment method of the invention.

### BRIEF DESCRIPTION OF THE DRAWING

This invention will be better understood upon reading the description of embodiments below, provided as a non-limiting example, in reference to the single appended figure, which diagrammatically shows a semiconductor material of which the surface was metallized according to the invention.

### DETAILED DESCRIPTION OF SPECIFIC EMBODIMENTS

Below, a method for treating a semiconductor material according to the invention is described. This method makes it possible to put the surface of said material in an electrically conductive state. This material, for example silicon carbide, is preferably monocrystalline.

In a first step of this method, the surface of the material is prepared so that said surface has bonds capable of absorbing hydrogen atoms. These are preferably dangling bonds.

To obtain these bonds, it is possible to proceed as follows: using a silicon source heated to 1300° C., a plurality of silicon monolayers are deposited on the surface of the substrate. With thermal annealing operations, a portion of the deposited silicon is evaporated, in a controlled manner, until the surface has a symmetric 3×2 organisation at the atomic scale (reconstruction). This symmetry of the surface can be controlled by electron diffraction.

In a second step, the passivation of one or more layers immediately underneath the surface thus prepared is performed by exposing said surface to a suitable compound, allowing for said passivation. This step will be discussed below.

In a third step, the surface thus prepared is metallized, by exposing it to hydrogen atoms.

To do this, it is possible to proceed as follows: the symmetric 3×2 surface is exposed to atomic hydrogen. To produce this atomic hydrogen, ultra pure molecular hydrogen, which is decomposed by an incandescent tungsten filament placed 2 cm from the sample, is used. During this exposure, the surface is kept at a temperature equal to 300° C.

The preparation of the surface and the combination of this surface with hydrogen cooperate to obtain the electrically conductive state of the surface.

The advantages of the method of the invention described above are discussed below.

In the case of the method described in document (1), only one abrupt interface was possible between a metal layer and a semiconductor layer, whereas the method according to the invention makes it possible to obtain a material in which two abrupt interfaces coexist:
a first abrupt interface between a semiconductor layer, constituted by the initial material, which is generally in bulk form, and the passivated layer, obtained during the implementation of the method, and
a second abrupt interface between the same passivated layer and the external metallized layer that is obtained during the final step of the method according to the invention.

This is of course extremely advantageous for the production of a MOS (Metal-Oxide-Semiconductor) transistor in which it is necessary to deposit a layer of metal on an oxide, which is itself deposited on a semiconductor.

For the passivation of the immediately underlying layers, the following steps are preferably performed:

i) oxidation of said layers, by exposing the surface, for example, to molecular oxygen or to a molecule containing oxygen, such as H₂O, CO or CO₂, or

ii) oxynitriding of said layers, by exposing the surface, for example, to NO or to N₂O, or

iii) nitriding of said layers, by exposing the surface, for example, to NH₃ or N₂.

It should be noted, in point i) above, that the molecule containing oxygen is not exclusively in gaseous form. It can be in the form of fine droplets, i.e. in the form of mist or a saturated atmosphere (water vapour, for example).

If the material is silicon carbide, the surface that is prepared so that it can absorb hydrogen atoms is preferably a surface that has been prepared so that it has, at the atomic scale, a symmetric 3×2 controlled organisation.

In particular, the material can have a 3×2 3C—SiC(100) surface, which surface is rich in silicon.

Such a preparation can be performed as follows: using a silicon source heated to 1300° C., a plurality of silicon monolayers are deposited on the surface of the substrate. With thermal annealing operations, a portion of the deposited silicon is evaporated, in a controlled manner, until the surface has a symmetric 3×2 organisation at the atomic scale (reconstruction). This symmetry of the surface can be controlled by electron diffraction.

However, the invention can be implemented on other surfaces, for example 3×3 hexagonal SiC surfaces and also on the 4×3 Si layer on 6H—SiC(0001) 4×3.

On this subject, we will refer to the following document:

(2) WO 01/39257A, “Silicon layer highly sensitive to oxygen and method for obtaining same”, invention of F. Amy, C. Brylinski, G. Dujardin, H. Enriquez, A. Mayne and P. Soukiassian.

Preferably, one or more layers selected from the layers immediately underneath the surface are passivated.

Advantageously, the layer having the number 3 or 4 is passivated, while leaving the upper layers unpassivated.

In addition, the metallization is not limited to the outermost layer: it can be performed on more than one atomic layer and can, for example, extend over the first three layers.

If the metallization is limited to the first, outermost, layer of the surface, it is possible to envisage that semiconductor layers are inserted between the external metallized layer and the deeper passivated layers.

Optionally, one or more layers of semiconductor material can be inserted between the metallized surface and the passivated underlying layers. Thus, more specifically in the case of a Si-terminated Si-type semiconductor material, the structure of the material is the following:

3 first layers constituted of Si (because the material is Si-terminated); then an area of SiC, then a passivated underlying area, then finally the original SiC substrate.

For example, with a SiC substrate, it is possible to oxidize below the surface of said substrate and leave an unoxidized Si layer at the surface.

Instead of hydrogen atoms, it is possible to use atoms of a metal element.

This metal element can be chosen, for example, from the metals of which the band d is full, jellium-type metals, alkaline metals (such as Cs, Rb, K or Na, in particular Na and K), and transition metals and silver.

In this case, to prepare the surface so that it has bonds capable of adsorbing atoms of the metal element, it is possible to proceed as follows: using a silicon source heated to 1300° C., a plurality of silicon monolayers are deposited on the surface of the substrate. With thermal annealing operations, a portion of the deposited silicon is evaporated, in a controlled manner, until the surface has a symmetric 3×2 or c (4×2) organisation at the atomic scale (reconstruction). This symmetry of the surface can be controlled by electron diffraction.

In addition, to metallize the prepared surface, it is possible to proceed as follows: using a source of a metal element, a plurality of monolayers are deposited on the surface of the substrate. It is possible to perform thermal annealing operations in order to evaporate some of the metal element, in a controlled manner, and to organise the deposition.

It is possible to reinforce the metallization, which has been obtained by means of hydrogen atoms or atoms of a metal element, by another exposure to oxygen.

Indeed, by way of example, after having metallized, by means of hydrogen, a pre-oxidized surface of SiC, this same surface was again exposed to oxygen, and it was noted that an annealing was required at a higher temperature to remove the hydrogen, and therefore the metallization.

Indeed, it is normally necessary to heat at less than 600° C. to remove the hydrogen.

However, after an additional exposure to oxygen, it is necessary to go above 900° C. to remove the hydrogen, and therefore the metallization, which also removes the oxygen.

Therefore, the post-oxidation protects the metallization or, as it were, passivates said metallization.

Therefore, with respect to the method described in document (1), the metallization is reinforced.

Below, it is shown, on the basis of an example that uses silicon carbide, that a superficial metallization takes place with hydrogen, as in the case of document (1), even if the surface of the silicon carbide has previously been passivated.

In this example, the surface of the SiC is passivated by superficial oxidation. However, this oxidation by exposure to oxygen can also be performed with molecules containing oxygen such as H₂O (in the gaseous state), NO, N₂O, CO, CO₂, at room temperature (around 20° C.) or at high temperature (from 25° C. to 1200° C.).

In addition, it has already been noted that the metallization caused by hydrogen was not removed by the oxidation or by other electron-accepting adsorbates.

According to the example considered, a clean, silicon-rich or Si-terminated SiC surface is lightly pre-oxidized by an exposure to oxygen ranging from 1 langmuir to 1000 langmuirs (1 langmuir (1 L) being equal to 10⁻⁶ torr.second, i.e. around 10⁻⁴ Pa·s), by keeping this surface at a temperature in the interval ranging from 25° C. to 800° C.

Then, the surface thus oxidized is exposed to atomic hydrogen (which can be obtained by exciting dihydrogen by a hot tungsten filament), the exposure ranging from a few langmuirs to a few hundred langmuirs. The metallization of the pre-oxidized surface is then obtained.

Another example of the invention is given below.

It is known that the preparation of a clean SiC surface consists of removing the native oxides, which is a delicate operation.

In this other example, it is sufficient, this time, to only very partially remove the native oxides, by a simple high-temperature rapid thermal annealing operation (or by a suitable chemical method), to remove most of these oxides, then to expose the surface to atomic hydrogen as described above.

After the second passivation step, at the end of which it can be considered that a native oxide is obtained, an additional “depassivation” step is performed, consisting of a high-temperature rapid thermal annealing operation, which partially removes the native oxides.

This step is of course followed by the surface preparation step and the metallization step.

In light of this other example, it can therefore clearly be seen that it is possible for the steps of the method of the invention not to be performed in the order “preparation then passivation then metallization”, since, in this other example, the order of steps is “passivation then depassivation then preparation then metallization”.

The partial removal of native oxides, which is implemented in this other example described above, is a simpler and faster operation than the total removal of said oxides, which is particularly advantageous in production.

The underlying passivated area thus obtained is relatively localized and, at the most, extends over just a few layers. This is therefore beneficial for the production of MOS transistors, as the interfaces are still sufficiently abrupt.

In this other example, the duration of the thermal annealing can be on the order of a few seconds to a few minutes and the temperature during this annealing can be on the order of 700° C. to 1300° C.

Another example of the invention is provided below.
A Si-rich and pre-oxidized 3C—SiC(100) 3×2 surface is prepared, by partial thermal removal of native oxides. Then, sequences, each including a silicon deposition followed by an annealing operation, are carried out.

This protocol results in a Si-rich 3C—SiC(100) surface, having two oxidation states and having a 3×2 pattern by LEED (low-energy electron diffraction).

Exposures to atomic hydrogen are performed at 300° C. using research-grade dihydrogen, which is separated by a heated tungsten filament.

This invention demonstrates new and very original properties that pave the way for applications in the fields of electronics, mechanics, biocompatibility, nanotechnology and microfabrication.

The metallization of the surface of a semiconductor, which has previously been oxidized/passivated, constitutes a property with absolutely no precedent.

It is very important, practically speaking, because it paves the way to the production of “ohmic” contacts at the surface of semiconductor materials, contacts which are naturally resistant to corrosion and/or moisture, without requiring the use of rare and expensive metals such as gold, which anyhow only partially perform their role.

The single appended figure shows a silicon carbide substrate 2, for example with a cubic structure, of which the surface 4 has been metallized in accordance with the invention, using atomic hydrogen or atoms of a metal element. The figure also shows a layer 5, which has been passivated prior to the metallization.

An ohmic contact results from such a metallization, performed locally on the substrate.

In addition, metallization with hydrogen is highly advantageous in the field of biocompatibility, for producing devices comprising interfaces between an electronic material and a biological material. Unlike most metals, hydrogen is biocompatible—it is an essential element for living matter—and the same is true of silicon carbide.

Returning to the single appended figure, the surface 4, metallized by means of hydrogen, can constitute such an interface between the material 2 and a biological material 6.

Finally, it is well known in tribology that the friction coefficient of surfaces having a metal nature is much lower than that of insulating or semiconductor surfaces.

Thus, the metallization with hydrogen, according to the invention, makes it possible to reduce the friction coefficient of the SiC surface and other semiconductors, in particular diamond.

The applications in mechanics and in particular in microfabrication or in nanofabrication, for example for producing nanomotors or nanogyroscopes, are therefore very beneficial. In this case, the hydrogen atoms act as an “atomic-scale lubricant”.

1. Method for treating a semiconductor material in order to put the surface of said material in an electrically conductive state, said method being characterised in that it includes the following steps:
a preparation step in which said surface is prepared so that it has bonds capable of adsorbing hydrogen atoms or atoms of a metal element,
a passivation step in which one or more layers are passivated, preferably immediately underneath said surface, by exposing said surface to a passivation compound, and
a metallization step in which the surface is metallized by exposure to hydrogen atoms or to atoms of the metal element,
the preparation and the combination of the surface with hydrogen or with the metal element cooperating to obtain the electrically conductive state of the surface,
and the method possibly also including a step of partial depassivation of the passivated layer(s), which follows the passivation step.

2. Method according to claim 1, wherein the semiconductor material is monocrystalline.

3. Method according to claim 1, wherein the passivation of the layer(s) is performed by oxidation of said layer(s), by exposing the surface to an oxidizing compound.

4. Method according to claim 1, wherein the passivation of the layer(s) is performed by oxynitriding said layer(s), by exposing the surface to an oxynitriding compound.

5. Method according to claim 1, wherein the passivation of the layer(s) is performed by nitriding said layer(s), by exposing the surface to a nitriding compound.

6. Method according to claim 1, wherein the bonds capable of adsorbing hydrogen atoms or atoms of the metal element are dangling bonds.

7. Method according to claim 1, wherein the semiconductor material is silicon carbide.

8. Method according to claim 7, wherein the surface of the silicon carbide is prepared so as to have, at the atomic scale, a symmetric 3×2 controlled organisation.

9. Method according to claim 1, wherein the layers that are passivated are layers immediately underneath the surface.

10. Method according to claim 1, wherein the metallized surface is exposed to oxygen so as to reinforce the metallization of said surface.

11. Method according to claim 1, wherein the depassivation step follows the passivation step and is itself followed by the preparation step, then by the metallization step.

12. Semiconductor material (2), preferably monocrystalline, whose surface (4) is metallized by the method according to claim 1.

13. Solid composite material including a semiconductor substrate of which the surface is metallized, said material being characterised in that said surface covers one or several atomic layers of the substrate, which are passivated and are preferably immediately underneath said surface, and in that the interface between the passivated atomic layer(s) and the substrate as well as the interface between the passivated atomic layer(s) and the metallized surface are abrupt.

14. Material according to claim 13, wherein the surface has dangling bonds, said surface being metallized by the adsorption of hydrogen atoms or atoms of a metal element.

15. Material according to claim 14, wherein the material (2) is silicon carbide with a cubic structure, of which the surface has, at the atomic scale, a symmetric 3×2 controlled organisation.

16. Method for producing an electrical contact (4) at the surface of a semiconductor material (2), wherein said contact is produced by metallizing the surface of the material by the method according to claim 1.

17. Method for producing an interface between a semiconductor material (2) and a biological material (6), wherein said interface (4) is produced by metallizing the surface of the material by the method according to claim 1.

18. Method for reducing the friction coefficient of a surface of a semiconductor material, wherein said surface is metallized by the method according to claim 1.
